(19) United States
(12) Patent Application Publication
(10) Pub. No.: US 2008/0303162 A1
(43) Pub. Date: Dec. 11, 2008

(54) SEMICONDUCTOR DEVICE

(76) Inventors: Hidetoshi Ishida, Osaka (JP); Manabu Yanagihara, Osaka (JP); Yasuhiro Uemoto, Shiga (JP); Daisuke Ueda, Osaka (JP)

Correspondence Address: MCDERMOTT WILL & EMERY LLP, 600 13TH STREET, NW, WASHINGTON, DC, 20005-3096, US

(21) Appl. No.: 12/100,245

(22) Filed: Apr. 9, 2008

(30) Foreign Application Priority Data
Jun. 7, 2007 (JP) 2007-151245
Nov. 30, 2007 (JP) 2007-310292

(51) Int. Cl. H01L 23/48

(52) U.S. Cl. 257/765; 257/E23.01

(57) ABSTRACT

A semiconductor device includes a layered structure including a first nitride semiconductor layer and a second nitride semiconductor layer that are sequentially formed over a substrate in this order. The second nitride semiconductor layer has a wider bandgap than the first nitride semiconductor layer. A first electrode and a second electrode are formed spaced apart from each other on the layered structure. A first insulating layer with a high breakdown field is formed in a region with electric field concentration between the first electrode and the second electrode over the layered structure. The first insulating layer has a higher breakdown field than air.

### CROSS REFERENCE TO RELATED APPLICATION

This application claims priority under 35 U.S.C. §119 on Patent Application No. 2007-151245 filed in Japan on Jun. 7, 2007 and Patent Application No. 2007-310292 filed in Japan on Nov. 30, 2007, the entire contents of which are hereby incorporated by reference.

### BACKGROUND OF THE INVENTION

1. Field of the Invention

The invention relates to a semiconductor device. In particular, the invention relates to a semiconductor device with a high breakdown voltage that is used for a power semiconductor device and the like.

2. Background Art

Smaller size and higher efficiency have been required for recent power switching devices. In order to meet these requirements, it is necessary to reduce a product (RonA) of an on-state resistance of a semiconductor element (on-resistance) and a device area while maintaining an off-state breakdown voltage. In general, the breakdown voltage and the on-resistance have a trade-off relationship, and the limit is determined by physical properties of a semiconductor material of a semiconductor device. Power semiconductor devices using wide bandgap semiconductors such as silicon carbide (SiC) or gallium nitride (GaN) have been developed in order to achieve higher capability than a conventional metal oxide semiconductor field effect transistor (MOSFET) or insulated gate bipolar transistor (IGBT), which are representative silicon (Si) devices.

In particular, the breakdown field of GaN based materials is higher than that of silicon (Si). Moreover, a high sheet carrier concentration can be implemented at a hetero interface between aluminum gallium nitride (AlGaN) and GaN (AlGaN/GaN hetero interface). Because of such characteristics, a nitride semiconductor has attracted much attention as a material for a high power semiconductor device which has both high breakdown voltage characteristics and high current characteristics.

An offset gate structure having an increased distance between a gate electrode and a drain electrode of a heterojunction field effect transistor (HFET) has been reported as a method for further improving a breakdown voltage of a nitride semiconductor device (e.g., see Japanese Laid-Open Patent Publication No. 2006-128646).

However, a breakdown voltage of a device using such a conventional nitride semiconductor is much lower than a value that is predicted from the maximum breakdown field of GaN. Even when electric field strength between a gate electrode and a drain electrode is reduced by increasing the gate-drain distance, the resultant breakdown voltage is only about 500V.

### SUMMARY OF THE INVENTION

The invention is made in order to solve the above problems and it is an object of the invention to implement a semiconductor device with a high breakdown voltage close to a value that is predicted from the maximum breakdown field of a semiconductor material.

In order to achieve the above object, a semiconductor device according to the invention includes an insulating layer with a high breakdown field that covers a region between a gate electrode and a drain electrode.

A semiconductor device according to the invention includes a substrate, a layered structure, a first electrode, a second electrode, and a first insulating layer. The layered structure includes a first nitride semiconductor layer and a second nitride semiconductor layer that are sequentially formed over the substrate in this order. The second nitride semiconductor layer has a wider bandgap than the first nitride semiconductor layer. The first electrode and the second electrode are formed spaced apart from each other on the layered structure. The first insulating layer is formed in a region with electric field concentration between the first electrode and the second electrode over the layered structure. The first insulating layer has a higher breakdown field than air.

The semiconductor device of the invention includes a first insulating layer having a higher breakdown field than air. Therefore, most of an electric field between the gate electrode and the drain electrode passes through the first insulating layer. Accordingly, breakdown of air can be effectively prevented from occurring between the gate electrode and the drain electrode. As a result, a semiconductor device having a very high breakdown voltage can be implemented.

### BRIEF DESCRIPTION OF THE DRAWINGS

FIG. 1 is a cross-sectional view of a semiconductor device according to an embodiment of the invention;

FIG. 2 is a graph showing the relationship between a gate-drain distance and a breakdown voltage of a semiconductor device without a first insulating layer;

FIG. 3 is a graph showing the relationship between a gate-drain distance and a breakdown voltage of a semiconductor device according to an embodiment of the invention;

FIG. 4 is a graph showing the relationship between a thickness of a first insulating layer and a breakdown voltage of a semiconductor device according to an embodiment of the invention;

FIG. 5 is a cross-sectional view of another structure of a semiconductor device according to an embodiment of the invention;

FIG. 6 is a graph showing an influence of a carrier concentration on a breakdown voltage of a semiconductor device according to an embodiment of the invention;

FIG. 7 is a graph showing the relationship between a carrier concentration and a breakdown voltage of a semiconductor device according to an embodiment of the invention;

FIG. 8 is a graph showing the relationship between a specific resistance of a substrate and a breakdown voltage of a semiconductor device according to an embodiment of the invention;

FIGS. 9A and 9B are graphs showing the relationship between a gate-drain distance and a breakdown voltage with and without a buffer layer for a semiconductor device;

FIGS. 10A and 10B show a semiconductor device according to a modification of an embodiment of the invention, where FIG. 10A is a plan view and FIG. 10B is a cross-sectional view taken along line Xb-Xb in FIG. 10A;

FIGS. 11A and 11B show another structure of a semiconductor device according to a modification of an embodiment of the invention, where FIG. 11A is a plan view and FIG. 11B is a cross-sectional view taken along line XIb-XIb in FIG. 11A; and

FIGS. 12A and 12B shown an example in which semiconductor devices according to a modification of an embodiment of the invention are integrated, where FIG. 12A is a plan view and FIG. 12B is a cross-sectional view taken along line XIIb-XIIb in FIG. 12A.

### DETAILED DESCRIPTION OF THE PREFERRED EMBODIMENTS

### Embodiment

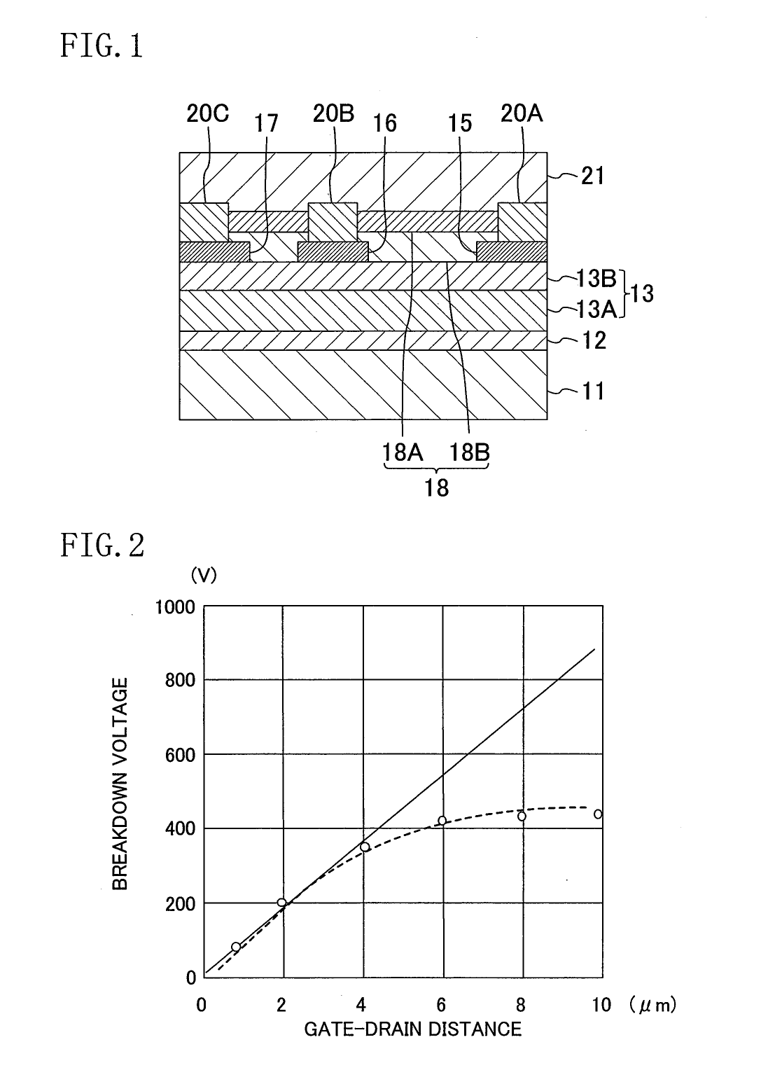

An embodiment of the invention will now be described with reference to the accompanying drawings. FIG. 1 shows a cross-sectional structure of a semiconductor device according to an embodiment of the invention. The semiconductor device of the embodiment is a heterojunction field effect transistor (HFET) using a nitride semiconductor.

As shown in FIG. 1, a layered structure 13 is formed on a substrate 11 with a buffer layer 12 interposed therebetween. In this embodiment, the buffer layer 12 is made of aluminum nitride (AlN) formed at 1,000° C. or higher. The layered structure 13 has a first nitride semiconductor layer 13A and a second nitride semiconductor layer 13B that are sequentially formed over the substrate 11 in this order. A channel is formed by a two-dimensional electron gas (2DEG) layer at the hetero interface between the first nitride semiconductor layer 13A and the second nitride semiconductor layer 13B. For example, the first nitride semiconductor layer 13A and the second nitride semiconductor layer 13B may be made of gallium nitride (GaN) and aluminum gallium nitride (AlGaN), respectively.

As described below, it is preferable that the buffer layer 12 is made of aluminum nitride (AlN) and it is particularly preferable that the buffer layer 12 has a thickness of 300 nm or more.

A first electrode 15, a second electrode 16, and a third electrode 17 are sequentially formed spaced apart from each other on the layered structure 13. In this embodiment, the first electrode 15 is a drain electrode, the second electrode 16 is a gate electrode, and the third electrode 17 is a source electrode. The distance between the gate electrode and the drain electrode is longer than the distance between the gate electrode and the source electrode in this embodiment. The distance between the gate electrode and the drain electrode is preferably 6 μm or more.

The first electrode 15, the second electrode 16, and the third electrode 17 are electrically connected with a first wiring 20A, a second wiring 20B, and a third wiring 20C, respectively. A second insulating layer 18 is formed on the layered structure 13 for forming the first wiring 20A, the second wiring 20B, and the third wiring 20C. In the example of FIG. 1, the second insulating layer 18 has a lower film 18A made of aluminum nitride (AlN) and an upper film 18B made of silicon nitride (SiN).

A first insulating layer 21 is formed on the second insulating layer 18. The first insulating layer 21 is an insulating layer with a high breakdown field. The breakdown field of the first insulating layer 21 is higher than that of air. More specifically, the first insulating layer 21 has a breakdown field of 30 kV/cm or higher, and preferably, 50 kV/cm or higher.

The reason why the semiconductor device of this embodiment has an improved breakdown voltage will now be described. FIG. 2 shows a breakdown voltage of a nitride semiconductor device that does not have a first insulating layer 21. As shown in FIG. 2, the breakdown voltage (drain-source breakdown voltage BVds) of the semiconductor device increases with increasing the distance between a gate electrode and a drain electrode (gate-drain distance Lgd). However, BVds is saturated and a breakdown voltage of 500V or higher cannot be realized even when Lgd is increased.

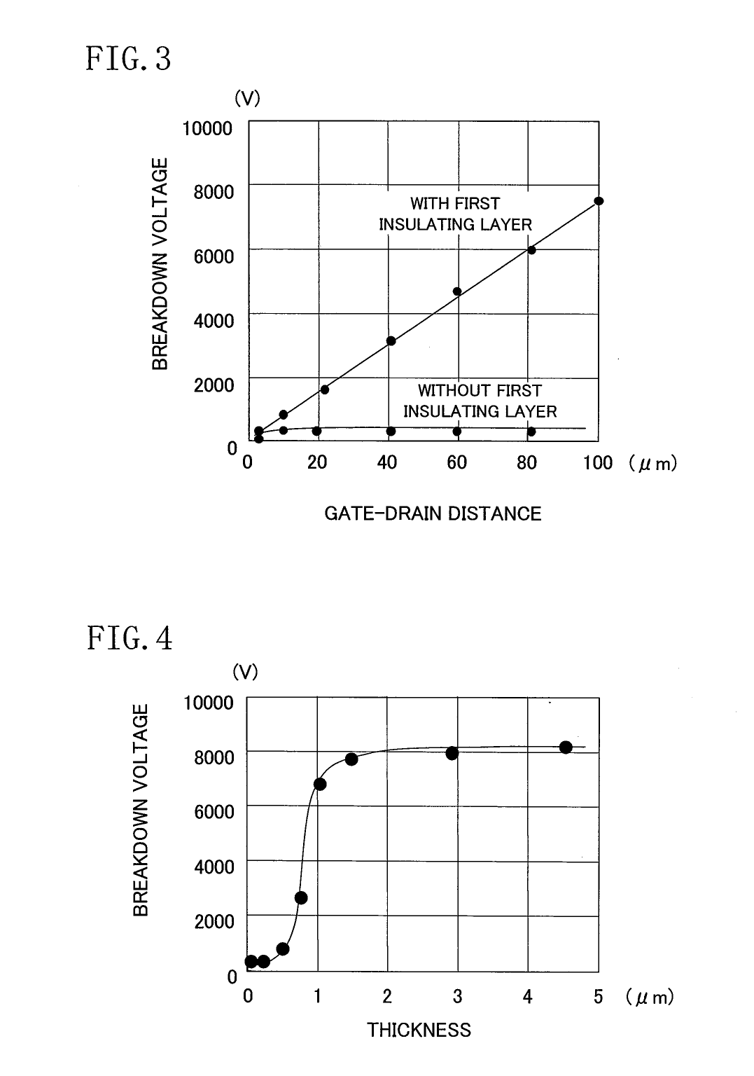

On the other hand, in the case where the first insulating layer 21 is provided as in this embodiment, BVds linearly increases with increasing Lgd, and a breakdown voltage of about 500 V to about 8,000 V or higher can be realized, as shown in FIG. 3.

The reason why BVds is saturated even when Lgd is increased has not been completely clarified so far. However, in the study by the inventors, the saturation phenomenon of BVds was hardly affected by the device structure, the material of the interlayer insulating film, the structure of the gate electrode, and the like. It is therefore considered that air discharge is involved in the saturation phenomenon of BVds. More specifically, in this embodiment, the surface of the semiconductor device is covered with the insulating layer having a higher breakdown field than air. With this structure, most of the electric field between the gate electrode and the drain electrode passes through the insulating layer with a high breakdown field. Accordingly, dielectric breakdown of air can be effectively suppressed and a high breakdown field that a nitride semiconductor material is supposed to have can be obtained. As a result, a very high breakdown voltage can be implemented.

This effect is obtained only by a semiconductor device using a nitride semiconductor having a high breakdown field. Even when an insulating layer with a high breakdown field is provided in a semiconductor device using a common semiconductor material such as silicon (Si), BVds is saturated when Lgd exceeds a prescribed range.

A breakdown voltage of a semiconductor device using a semiconductor material such as Si is determined by an impurity concentration of the semiconductor material. For example, as a reverse bias that is applied to a Schottky junction is increased, a depletion layer expands near Schottky metal and electric field strength at the end of the Schottky metal increases gradually. The Schottky junction is broken down when the electric field strength reaches the breakdown field of the semiconductor material. In this case, the junction is broken down even when there is a sufficient margin for the depletion layer to expand. In other words, even when the distance Lgd between a gate electrode (Schottky electrode) and an adjacent drain electrode (ohmic electrode) is increased, the Schottky breakdown voltage does not increase at a prescribed Lgd or more, and shows a tendency of being saturated. However, the inventors founded that such a phenomenon is not observed in a nitride semiconductor and that by providing an insulating layer with a high breakdown field, the breakdown voltage can be increased to any value by increasing the distance Lgd as shown in FIG. 3.

The inventors also found that such specific properties of a nitride semiconductor can be explained by the following model: in a nitride semiconductor layer such as a GaN layer, polarized charges having opposite polarities and the same density are generated on the top and bottom surfaces of the GaN layer, respectively. However, free carriers that are opposite in polarity to the polarized charges (i.e., electrons and holes) are induced on the top and bottom surfaces of the GaN layer, respectively. Therefore, the GaN layer is retained approximately electrically neutral. In the case where a reverse bias is applied to the GaN layer, the free carriers are removed and only the polarized charges remain. These polarized charges are the same in density and opposite in polarity, the amount of charges becomes zero on average. Since the amount of charges is zero, the GaN layer acts as if it were an insulator and the internal electric field strength is constant regardless of the location. Therefore, BVds is not saturated and can be increased to any value by increasing Lgd. Such excellent breakdown voltage characteristics obtained by providing an insulating layer with a high breakdown field can be obtained only when a nitride semiconductor material is used.

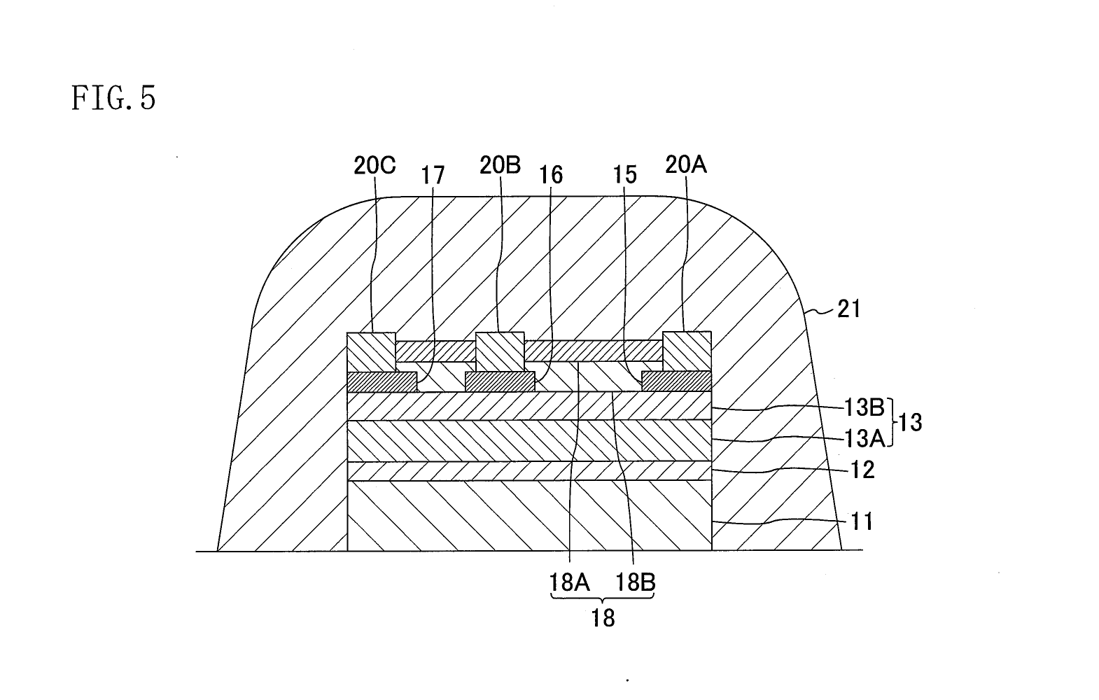

In FIG. 1, the first insulating layer 21 is formed over the whole surface of the layered structure 13. However, the first insulating layer 21 may be formed so as to cover at least a region having a higher electric field than a breakdown field of air between the gate electrode and the drain electrode. As shown in FIG. 4, the breakdown voltage is increased with an increase in thickness of the first insulating layer 21. The thickness of the first insulating layer 21 is preferably at least 500 nm or more, and more preferably, 1 μm or more. As shown in FIG. 5, the first insulating layer 21 may alternatively be formed so as to mold the entire semiconductor device.

The first insulating layer 21 may be made of any material as long as the material has a higher breakdown field than air. For example, the first insulating layer 21 may be made of AlN that is an inorganic material, a silicon-based polymer made of a silane derivative, a benzocyclobutene (BCB), a polybenzoxazole (PBO), a polyimide, or the like. The first insulating layer 21 may be formed by a sputtering method, a chemical vapor deposition (CVD) method, a spin coating method, or the like depending on the material. The breakdown field of the first insulating layer 21 can thus be made higher than the breakdown field of air.

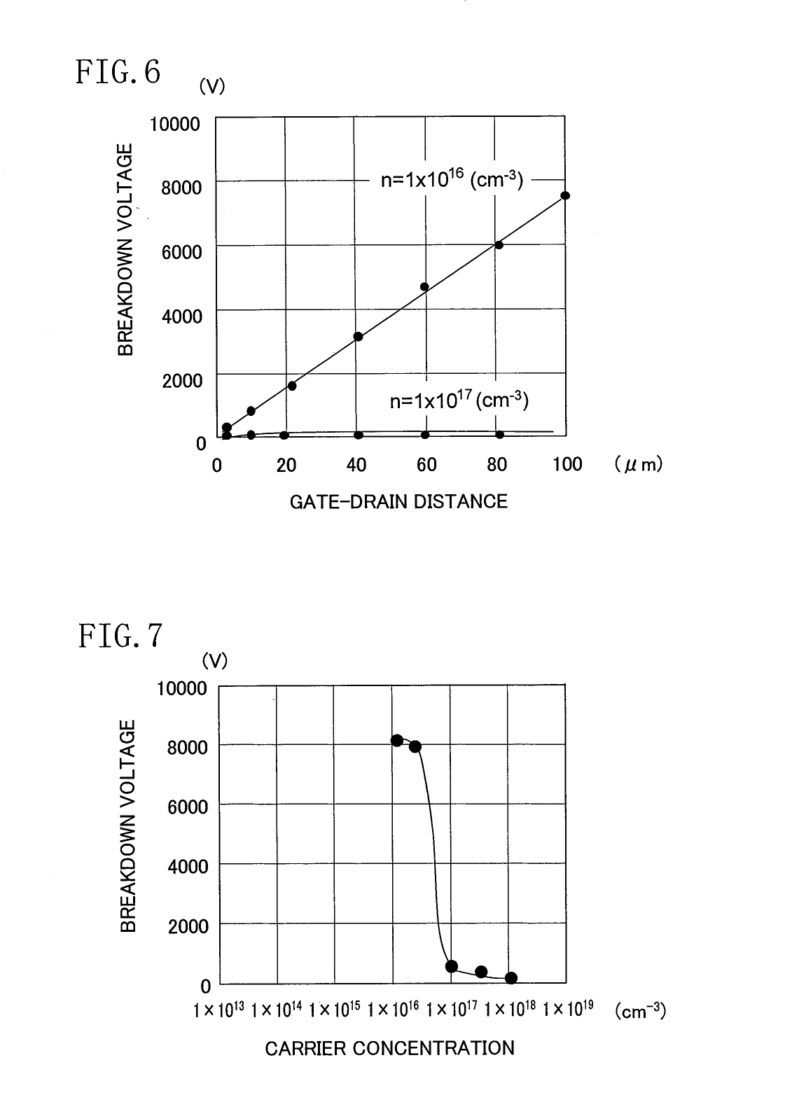

The lower the carrier concentration of the first nitride semiconductor layer 13A is, the more likely the depletion layer is to expand from the gate end toward the drain when the electric field strength between the gate and the drain is increased. As a result, the electric field strength between the gate and the drain is reduced. Therefore, in order to improve the breakdown voltage of the semiconductor device, it is preferable that the first nitride semiconductor layer 13A has a lower carrier concentration. FIG. 6 shows the relationship between Lgd and BVds regarding two semiconductor devices that are different in carrier concentration of the first nitride semiconductor layer 13A. In the case where the carrier concentration of the first nitride semiconductor layer 13A is 1×10¹⁶ cm⁻³, the breakdown voltage linearly increases with an increase in Lgd and the breakdown voltage of 500 V or higher is implemented. However, in the case where the carrier concentration of the first nitride semiconductor layer 13A is 1×10¹⁷ cm⁻³, the effect of improving the breakdown voltage is small. FIG. 7 is a plot of the relationship between the carrier concentration and the breakdown voltage. As shown in FIG. 7, in order to implement a high breakdown voltage, it is preferable that the carrier concentration is 5×10¹⁶ cm⁻³ or less.

In the example of FIG. 1, the second insulating layer 18 is formed between the first insulating layer 21 and the layered structure 13 in order to form the first wiring 20A, the second wiring 20B, and the third wiring 20C. However, in order to improve the breakdown voltage of the semiconductor device, the second insulating layer 18 is not necessarily required. In the example of FIG. 1, the first wiring 20A, the second wiring 20B, and the third wiring 20C extend through the second insulating layer 18 and are in contact with the first insulating layer 21. However, the first wiring 20A, the second wiring 20B, and the third wiring 20C are not necessarily in contact with the first insulating layer 21.

In the case where the second insulating layer 18 is provided, it is preferable that the second insulating layer 18 has a higher relative permittivity than the first insulating layer 21. For example, in the case where the second insulating layer 18 is made of AlN and SiN, the first insulating layer 21 may be made of a material having a relative permittivity lower than 9.1 that is a relative permittivity of AlN. By making the relative permittivity of the first insulating layer 21 lower than the second insulating layer 18, the electric field strength near the region between the gate electrode and the drain electrode can be reduced. As a result, a semiconductor device having a higher breakdown voltage can be implemented.

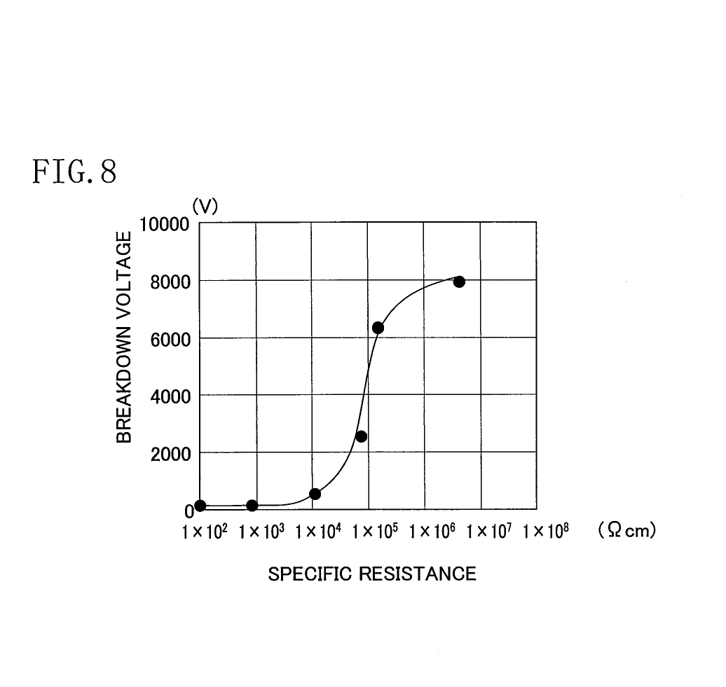

The substrate 11 may be made of any material as long as the layered structure 13 can be formed. For example, the substrate 11 may be made of sapphire, silicon, silicon carbide (SiC), GaN, AlN, diamond, or the like. Note that, as shown in FIG. 8, the breakdown voltage of the semiconductor device can be improved as the specific resistance of the substrate is higher. It is therefore preferable that the substrate has a specific resistance of 0.1 MΩcm or higher.

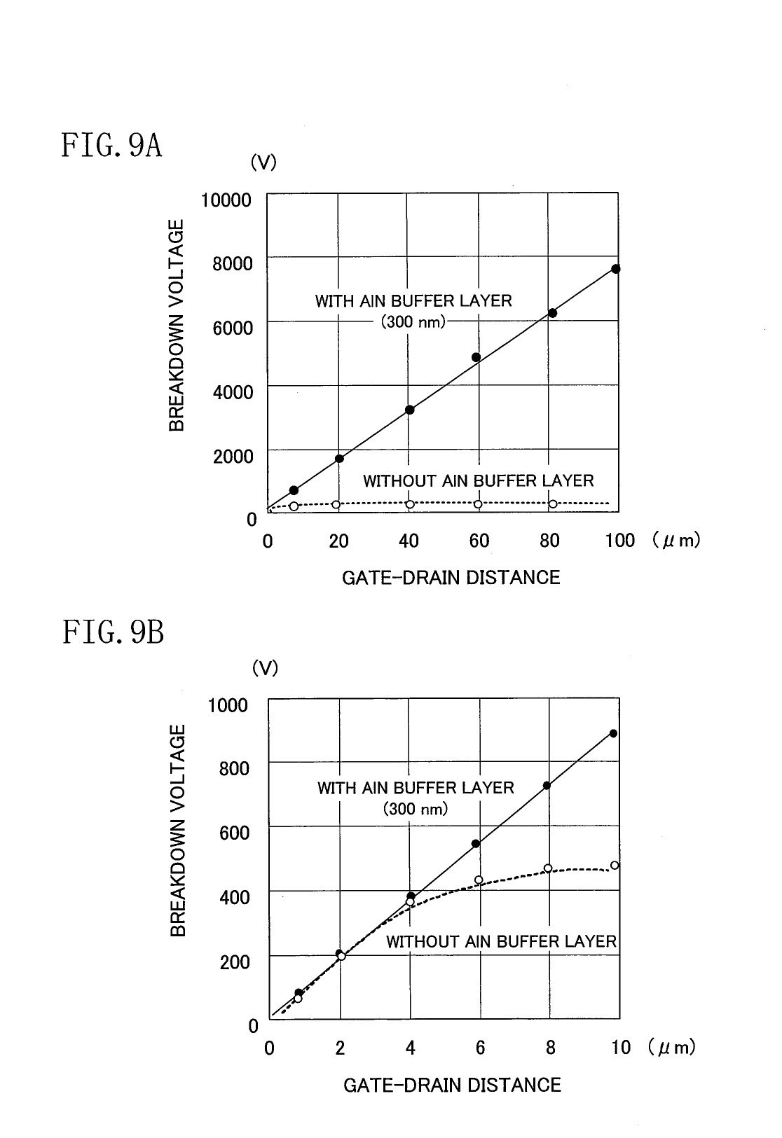

Hereinafter, the effects obtained by forming the buffer layer 12 from AlN in the semiconductor device of this embodiment will be described. FIGS. 9A and 9B show the relationship between the distance between the gate electrode and the drain electrode and the breakdown voltage. FIG. 9B is an enlarged graph of a part of the graph shown in FIG. 9A.

As shown in FIGS. 9A and 9B, the breakdown voltage is improved as the distance between the gate electrode and the drain electrode is increased. However, in the case where the buffer layer 12 made of AlN is not provided, the breakdown voltage is saturated at about 400 V as shown by the dashed line in FIGS. 9A and 9B. On the other hand, in the case where the buffer layer 12 made of AlN is provided, the breakdown voltage increases in proportion to the distance between the gate electrode and the drain electrode and a breakdown voltage of at least about 8,000 V can be implemented, as shown by the solid line in FIGS. 9A and 9B. This effect significantly appears especially in the case where the distance between the gate electrode and the drain electrode is 6 μm or more. In order to reduce a leakage current, it is preferable that AlN has high crystallinity. It is therefore preferable that the buffer layer 12 has a thickness of 300 nm or more so that AlN having excellent crystallinity can be obtained.

A breakdown voltage of 400 V or higher can be realized in the case where the distance between the gate electrode and the drain electrode is 6 μm or more. A field effect transistor having a breakdown voltage of 400 V or higher can be used in a very wide range of applications.

### Modification of the Embodiment

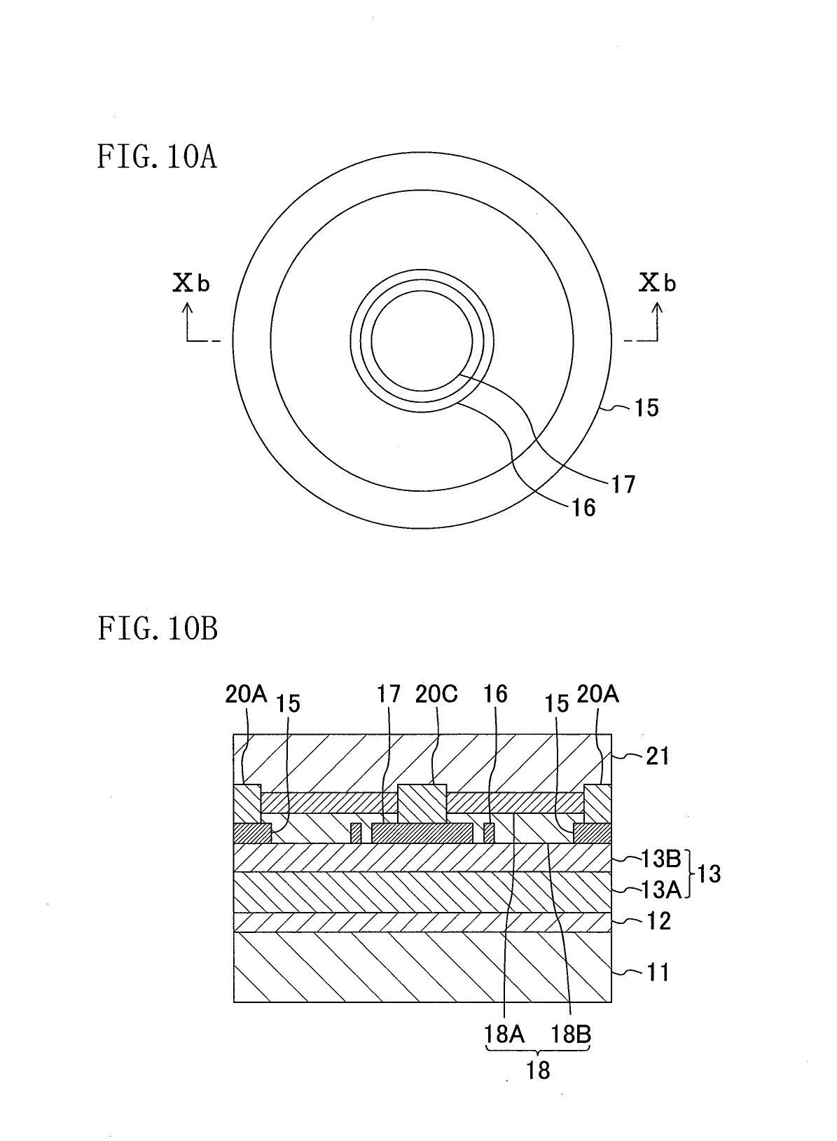

Hereinafter, a modification of the embodiment of the invention will be described with reference to the figures. FIGS. 10A and 10B show a semiconductor device according to the modification. FIG. 10A shows a planar structure and FIG. 10B is a cross-sectional structure taken along line Xb-Xb in FIG. 10A. In FIGS. 10A and 10B, the same elements as those of FIG. 1 are denoted by the same reference numerals and characters and description thereof will be omitted.

In the semiconductor device of this modification, a ring-shaped second electrode 16 and a ring-shaped first electrode 15 are formed so as to surround a circular third electrode 17. In this modification, the first electrode 15 is a drain electrode, the second electrode 16 is a gate electrode, and the third electrode 17 is a source electrode.

With this structure, the distance between the gate electrode and the drain electrode is constant. Accordingly, the electric field strength between the gate electrode and the drain electrode becomes constant, and a large electric field is not be generated locally. As a result, a very high breakdown voltage can be implemented.

In this modification, the third electrode 17 has a planar circular shape and the second electrode 16 and the first electrode 15 are arranged concentrically with the third electrode 17. However, the shape of the third electrode 17 is not limited as long as the distance between the second electrode 16 and the first electrode 15 is approximately constant. The third electrode 17 may have a planar oval shape. Alternatively, the third electrode 17 may have a polygonal shape such as a square or equilateral hexagonal shape. However, it is preferable that the third electrode 17 does not contain any angle part because electric field concentration is less likely to occur.

The first electrode 15 (drain electrode) may be provided in the middle and the second electrode 16 (gate electrode) and the third electrode 17 (source electrode) may be arranged in a ring pattern.

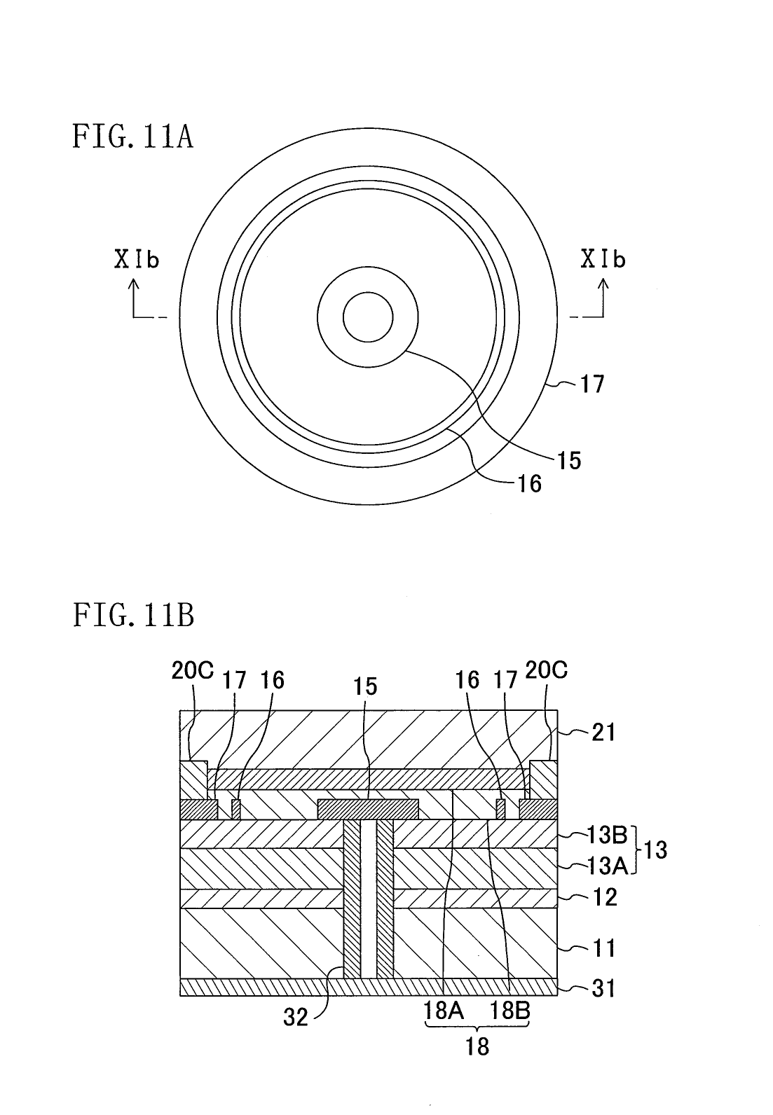

In this case, as shown in FIGS. 11A and 11B, a rear electrode 31 made of a metal layer may be formed on the opposite surface (rear surface) of the substrate 11 to the layered structure 13 and the drain electrode and the rear electrode 31 may be electrically connected with each other through an interconnect (conductive via-hole) 32 that extends through the layered structure 13 and the substrate 11.

With this structure, the drain electrode can be connected to the rear surface of the device without extending a drain wiring, which can reduce a region where a drain wiring and a gate wiring overlap each other on the surface of the semiconductor device. In general, a very high voltage is applied to the region where the drain wiring and the gate wiring overlap each other. Therefore, the thickness of the second insulating layer 18 for insulating the wirings from each other can be reduced by reducing the overlap region. As a result, a semiconductor device having a very high breakdown voltage can be implemented with an interlayer insulating film having a practical thickness.

Moreover, not only a current but heat generated in the semiconductor device can be released to the rear surface of the substrate through the interconnect 32, and heat resistance of the semiconductor device can be reduced. As a result, very high breakdown voltage characteristics and heat release characteristics are simultaneously implemented.

Note that the interconnect 32 may be formed by forming a through hole that extends from the rear surface of the substrate 11 to the bottom surface of the first electrode 15 and forming an electrically conductive material on the sidewall of the through hole. Alternatively, the through hole may be filled with an electrically conductive material.

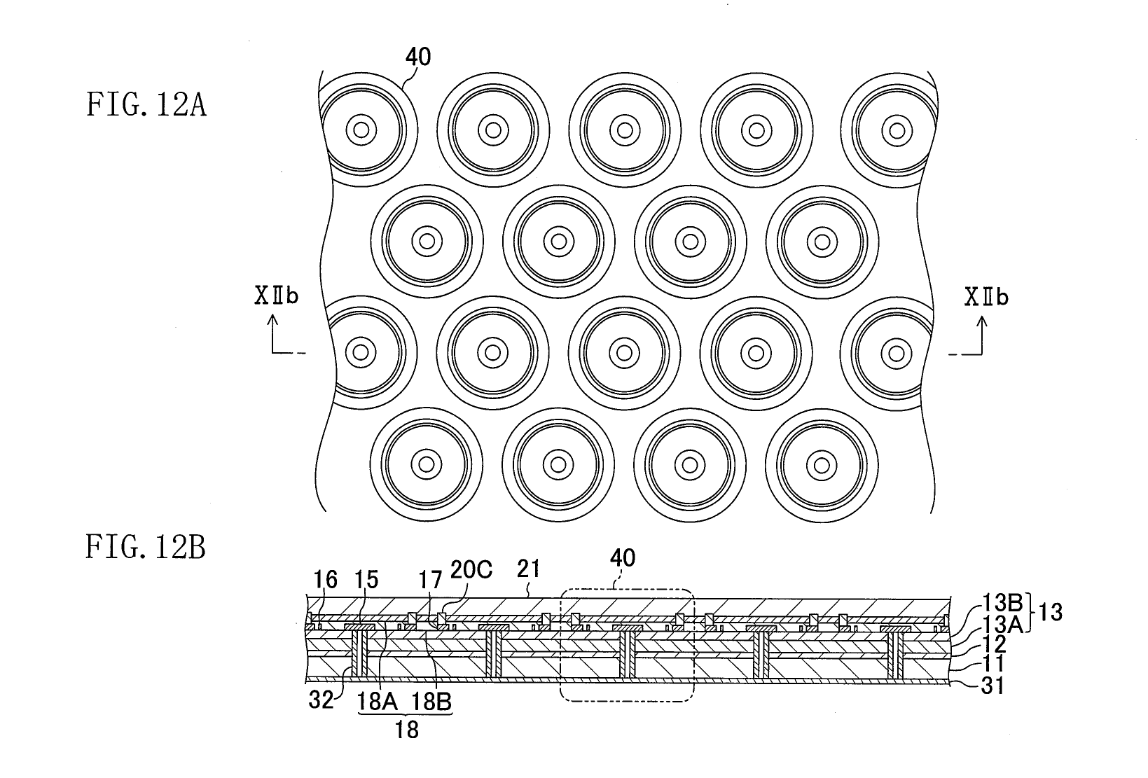

Extending the drain electrode to the rear surface of the substrate facilitates integration of semiconductor devices. FIGS. 12A and 12B show an example in which the semiconductor devices of the modification are integrated. FIG. 12A shows a planar structure and FIG. 12B is a cross-sectional structure taken along line XIIb-XIIb in FIG. 12A.

As shown in FIGS. 12A and 12B, a plurality of unit transistors 40 each formed by the semiconductor device of this modification are formed in close-packed arrangement. A drain electrode of each unit transistor 40 is electrically connected with an integrally formed rear electrode 31 through an interconnect 32. The respective gate electrodes of the unit transistors 40 are electrically connected with each other though wiring and the respective source electrodes of the unit transistors 40 are electrically connected with each other through wiring. A multiplicity of unit transistors 40 are thus connected in parallel with each other. As a result, the maximum current of the semiconductor device can be dramatically increased. Moreover, since the drain wiring and the gate wiring hardly overlap each other, the thickness of the interlayer insulating film for insulating the wirings from each other need not be increased even when a high voltage is used. Accordingly, very high breakdown voltage characteristics and large current characteristics can be realized simultaneously.

In the embodiment and the modification of the invention, the buffer layer 12 is made of AlN formed at a high temperature. However, the buffer layer 12 may be made of any material as long as the layered structure 13 can be formed with good crystallinity. It should be noted that it is preferable that the buffer layer 12 is made of a material that can reduce a leakage current in the buffer layer 12.

The layered structure 13 may have any structure as long as a channel layer in which electrons travel approximately in parallel with a main surface of the substrate 11 can be formed. Instead of a nitride semiconductor, other wide-gap semiconductors such as SiC may be used.

The field effect transistor having the first electrode 15 as a drain electrode, the second electrode 16 as a gate electrode, and the third electrode 17 as a source electrode is described in the embodiment and the modification of the invention. However, the same effects can be obtained in a Schottky barrier diode having an anode electrode and a cathode electrode, and the like. The source electrode and the drain electrode as ohmic electrodes may have any structure as long as the source and drain electrodes are in ohmic contact with the channel. The gate electrode may have any structure as long as the gate electrode can control the channel. In the embodiment and the modification of the invention, the gate-drain distance is longer than the gate-source distance. However, the gate-drain distance may be the same as the gate-source distance.

As has been described above, the invention can implement a semiconductor device with a high breakdown voltage, and is useful as a semiconductor device that is used especially for a power semiconductor device and the like, such as a high output power switching element, a high power high frequency element, and the like.

The description of the embodiments of the invention is given above for the understanding of the invention. It will be understood that the invention is not limited to the particular embodiments described herein, but is capable of various modifications, rearrangements, and substitutions as will now become apparent to those skilled in the art without departing from the scope of the invention. Therefore, it is intended that the following claims cover all such modifications and changes as fall within the true spirit and scope of the invention.

What is claimed is:

1. A semiconductor device, comprising:
a substrate;
a layered structure including a first nitride semiconductor layer and a second nitride semiconductor layer that are sequentially formed over the substrate in this order, the second nitride semiconductor layer having a wider bandgap than the first nitride semiconductor layer;
a first electrode and a second electrode that are formed spaced apart from each other on the layered structure; and
a first insulating layer formed in a region with electric field concentration between the first electrode and the second electrode over the layered structure, the first insulating layer having a higher breakdown field than air.

2. The semiconductor device according to claim 1, wherein the first insulating layer has a breakdown field of 50 kV/cm or more.

3. The semiconductor device according to claim 1, wherein the first insulating layer has a thickness of 500 nm or more.

4. The semiconductor device according to claim 1, wherein the substrate has a specific resistance of 0.1 MΩcm or more.

5. The semiconductor device according to claim 1, wherein the first nitride semiconductor layer has a carrier concentration of 5×10¹⁶ cm⁻³ or less.

6. The semiconductor device according to claim 1, further comprising a second insulating layer formed between the first insulating layer and the layered structure, wherein the second insulating layer has a higher permittivity than the first insulating layer.

7. The semiconductor device according to claim 1, further comprising a third electrode formed on the layered structure, wherein the second electrode surrounds the first electrode, the third electrode surrounds the second electrode, and a distance between the first electrode and the second electrode is approximately constant.

8. The semiconductor device according to claim 7, further comprising:
a metal layer formed on an opposite surface of the substrate to the layered structure; and
an interconnect extending through the layered structure and the substrate for electrically connecting the first electrode and the metal layer with each other.

9. A semiconductor device, comprising a plurality of unit transistors, each of the unit transistors being the semiconductor device of claim 8 and formed on a single substrate.

10. The semiconductor device according to claim 1, further comprising a third electrode formed on the layered structure, wherein the second electrode surrounds the third electrode, the first electrode surrounds the second electrode, and a distance between the first electrode and the second electrode is approximately constant.

11. The semiconductor device according to claim 10, further comprising:
a metal layer formed on an opposite surface of the substrate to the layered structure; and
an interconnect extending through the layered structure and the substrate for electrically connecting the third electrode and the metal layer with each other.

12. The semiconductor device according to claim 9, further comprising a wiring electrically connected with the first electrode, wherein the wiring does not overlap the second electrode.

13. The semiconductor device according to claim 1, further comprising a buffer layer of aluminum nitride formed between the substrate and the first nitride semiconductor layer.

14. The semiconductor device according to claim 13, wherein the buffer layer has a thickness of 300 nm or more.

15. The semiconductor device according to claim 13, wherein a distance between the first electrode and the second electrode is 6 μm or more.

16. The semiconductor device according to claim 13, wherein a breakdown voltage between the first electrode and the second electrode is 400 V or more.

17. The semiconductor device according to claim 1, wherein the first insulating layer is made of aluminum nitride, benzocyclobutene, or polybenzoxazole.
